(19) United States
(12) Patent Application Publication
(10) Pub. No.: US 2016/0238636 A1
(43) Pub. Date: Aug. 18, 2016

(54) METHOD FOR ESTIMATING LIFETIME OF CATHODE IN ELECTRON BEAM LITHOGRAPHY APPARATUS

(71) Applicant: NUFLARE TECHNOLOGY, INC., YOKOHAMA-SHI (JP)

(72) Inventor: MASAYUKI ITO, YOKOHAMA-SHI (JP)

(73) Assignee: NUFLARE TECHNOLOGY, INC., YOKOHAMA-SHI (JP)

(21) Appl. No.: 15/040,532

(22) Filed: Feb. 10, 2016

(30) Foreign Application Priority Data
Feb. 16, 2015 (JP) 2015-027431

(51) Int. Cl. G01R 19/00; H01J 37/317

(52) U.S. Cl. CPC G01R 19/0061; H01J 37/3174; H01J 2237/24535; H01J 2237/24521; H01J 2237/24592

(57) ABSTRACT

A method for estimating a lifetime of a cathode in an electron beam lithography apparatus according to an embodiment, includes: calculating emittance of the cathode by using a lifetime reference value of the cathode; calculating an emitter lifetime diameter of the cathode by using the emittance; writing a pattern on a target object by using an electron beam emitted from the cathode; measuring emission current of the electron beam; calculating an emitter diameter by using the emission current; determining a regression formula of a change with time of the emitter diameter; and estimating the lifetime of the cathode by using the regression formula and the emitter lifetime diameter.

### CROSS-REFERENCE TO RELATED APPLICATION

This application is based upon and claims the benefit of priority from Japanese Patent Applications No. 2015-027431, filed on Feb. 16, 2015, the entire contents of which are incorporated herein by reference.

### FIELD OF THE INVENTION

Embodiments described herein relate generally to a method for estimating a lifetime of a cathode in an electron beam lithography apparatus. The embodiment relates to a method for estimating a lifetime of a cathode, for example, used for an electron beam lithography apparatus that irradiates a target object with a predetermined dose of an electron beam so as to write a pattern.

### BACKGROUND OF THE INVENTION

A lithography technique leads development of miniaturization of semiconductor devices. The lithography technique is an important process that generates a pattern, such as a circuit pattern. Recently, as LSIs have been highly integrated, a circuit pattern linewidth required for the semiconductor devices has been miniaturized year by year. A high-precision original pattern (also referred to as a “reticle” or a “mask”) is required in order to form a desired circuit pattern to the semiconductor devices. A lithography technique with a charged particle beam (charged particle ray) using charged particles, such as electrons, has essentially excellent resolution. The lithography technique is used so as to manufacture high-precision original patterns.

FIG. 11 is a schematic view for describing operation of a variable-shaped electron beam lithography apparatus. Note that, the variable-shaped electron beam lithography apparatus is an example of charged particle beam lithography apparatuses. The variable-shaped electron beam (EB: Electron beam) lithography apparatus operates as follows: Firstly, a quadrilateral, for example, a rectangular opening 411 for forming an electron beam 330 is formed on a first aperture plate 410. A variable-shaped opening 421 is formed on a second aperture plate 420. The variable-shaped opening 421 forms the electron beam 330 that has passed through the opening 411, into a desired quadrilateral shape. A deflector deflects the electron beam 330 that has been emitted from a charged particle source 430 and that has passed through the opening 411. A target object 340 mounted on a stage is irradiated with the electron beam 330 after passing through a part of the variable-shaped opening 421. The stage continuously moves in a predetermined direction (for example, an X direction) during writing. As described above, a quadrilateral shape that can pass through both the opening 411 and the variable-shaped opening 421, is written in a writing region of the target object 340. A method for forming an arbitrary shape by causing the electron beam 330 to pass through both of the opening 411 and the variable-shaped opening 421, is referred to as a variable-shaped method.

It is necessary to increase current density of the beam in order to improve throughput of the electron beam lithography apparatus. It is necessary to set a cathode temperature of an electron gun assembly to a high temperature in order to achieve the large current density. However, if the cathode is set to the high temperature, since an evaporation speed of a cathode material increases, a top end shape of the cathode varies while writing. Therefore, a lifetime of the cathode can be preferably estimated in order to perform writing with high-precision.

### SUMMARY OF THE INVENTION

A method for estimating a lifetime of a cathode in an electron beam lithography apparatus according to an embodiment, includes: calculating emittance of the cathode by using a lifetime reference value of the cathode; calculating an emitter lifetime diameter of the cathode by using the emittance; writing a pattern on a target object by using an electron beam emitted from the cathode; measuring emission current of the electron beam; calculating an emitter diameter by using the emission current; determining a regression formula of a change with time of the emitter diameter; and estimating the lifetime of the cathode by using the regression formula and the emitter lifetime diameter.

### BRIEF DESCRIPTION OF THE DRAWINGS

FIG. 1 is a conceptual diagram of a configuration of a variable-shaped electron beam lithography apparatus according to the present embodiment;

FIG. 2 is a conceptual diagram for describing a method for adjusting current density of an electron beam according to the present embodiment;

FIG. 3 is a flow chart of a series of main processes of the method for adjusting current density of an electron beam according to the present embodiment;

FIGS. 4A and 4B are exemplary graphical representations of current density J and a target value of emission current Iₑ according to the present embodiment, respectively;

FIG. 5 is a schematic view of the electron beam according to the present embodiment;

FIGS. 6A and 6B are schematic views of an emitter according to the present embodiment;

FIGS. 7A to 7C are schematic views of distributions of the electron beam on a target object according to the present embodiment;

FIG. 8 is a graphical representation of the relationship between emittance of a cathode and an actual measured emitter diameter according to the present embodiment;

FIG. 9 is a flow chart of a series of main processes of a method for estimating a lifetime of the cathode in the electron beam lithography apparatus according to the present embodiment;

FIG. 10 is a graphical representation of a change with time of the emitter diameter of the electron beam lithography apparatus according to the present embodiment; and

FIG. 11 is a schematic view for describing operation of a variable-shaped electron beam lithography apparatus in the related art.

### DETAILED DESCRIPTION OF THE EMBODIMENTS

An embodiment of the present disclosure will be described with reference to the drawings.

Note that, in the following descriptions, “on a target object” represents on-a-surface of the target object, the surface being irradiated with an electron beam.

### Embodiment

A method for estimating a lifetime of a cathode in an electron beam lithography apparatus according to the present embodiment, includes: calculating emittance of the cathode by using a lifetime reference value of the cathode; calculating an emitter lifetime diameter of the cathode by using the emittance; writing a pattern on a target object by using an electron beam emitted from the cathode; measuring emission current of the electron beam; calculating an emitter diameter by using the emission current; determining a regression formula of a change with time of the emitter diameter; and estimating the lifetime of the cathode by using the regression formula and the emitter lifetime diameter.

According to the following embodiment, a variable-shaped electron beam lithography apparatus will be described as an exemplary electron beam lithography apparatus.

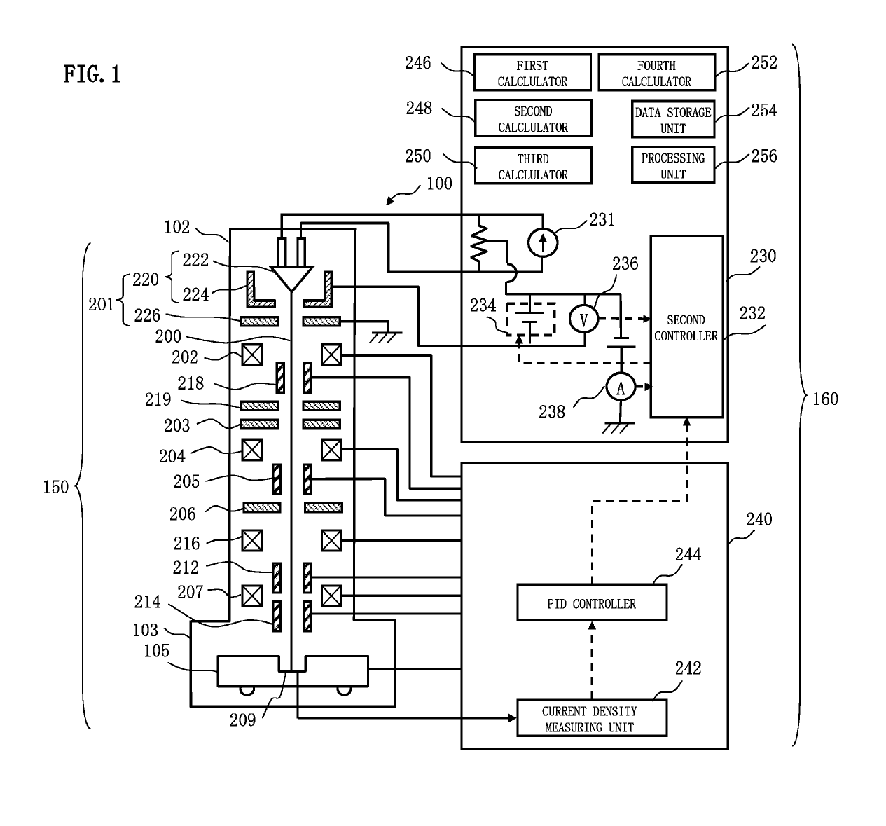

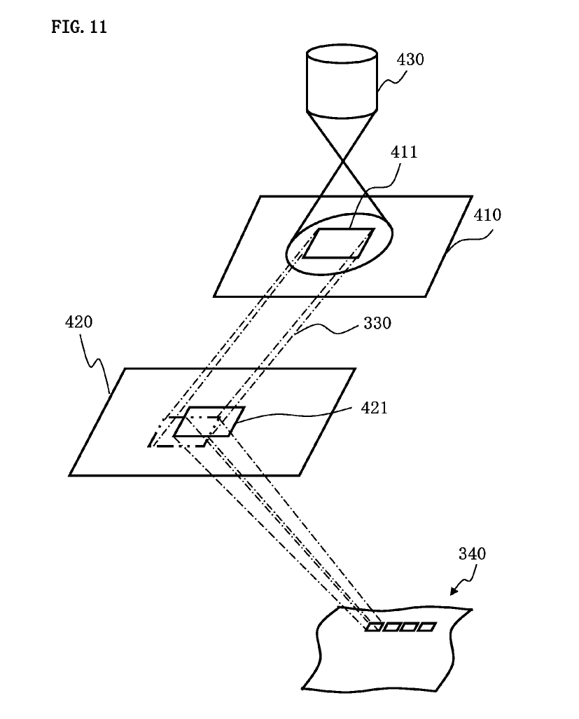

FIG. 1 is a conceptual diagram of a configuration of the variable-shaped electron beam lithography apparatus according to the present embodiment. The variable-shaped electron beam lithography apparatus 100 includes a pattern writing mechanism 150 and a first controller 160. The pattern writing mechanism 150 includes an electron optical column 102 and a pattern writing chamber 103. The electron optical column 102 includes an electron gun assembly 201, an illumination lens 202, a first forming aperture plate 203, a forming lens 204, a forming deflector 205, a second forming aperture plate 206, an objective lens 207, a sub-deflector 212, a main deflector 214, a reducing lens 216, a blanking (BLK) deflector 218, and a blanking (BLK) aperture plate 219 disposed therein. A beam absorbing electrode (Faraday cup 209) for measuring current of an electron beam 200, is disposed on an XY stage 105. The electron gun assembly 201 has a cathode 220 and an anode 226. The cathode 220 has an emitter 222 and a Wehnelt electrode 224. The anode 226 is grounded (earth fault). The XY stage 105 is disposed in the pattern writing chamber 103. A target object 340, such as a mask, is disposed on the XY stage 105 (refer to FIG. 11). The target object is an object to be written during writing. The target object 340 includes an exposure mask used upon manufacturing of a semiconductor device. The target object 340 includes a mask blank on which nothing is written. The mask blank includes a light shielding film, such as chromium (Cr), formed on a glass substrate, and coated with resist. The electron optical column 102 is detachable, for example, from the pattern writing chamber 103.

The first controller 160 has an electron gun assembly power source 230 and a pattern writing control circuit 240. A constant current source 231 supplies a predetermined heating current to both poles of the emitter 222 inside the electron gun assembly power source 230. A variable voltage source 234 applies a predetermined bias voltage (Wehnelt voltage) between the Wehnelt electrode 224 and an intermediate voltage between the poles of the emitter 222. One end of a predetermined direct current power source is disposed at the intermediate voltage between the poles of the emitter 222, in parallel with the variable voltage source 234. The other end of the direct current power source is grounded through an ammeter 238. A voltmeter 236 is disposed in parallel with the variable voltage source 234. A current density measuring unit 242 and a proportional-integral-derivative (PID) controller 244 are disposed in the pattern writing control circuit 240. The PID control is control based on the amount of correction proportional to deviation from a target value, the amount of correction acquired by integrating deviation from a previous target value, and the amount of correction acquired by differentiating time variation of the deviation from the target value. In FIG. 1, components necessary for describing the present embodiment, are illustrated. Needless to say, the lithography apparatus 100 includes typically necessary other components.

Inside the electron gun assembly power source 230, a second controller 232 detects, by the voltmeter 236, and performs variable control to the bias voltage (Wehnelt voltage) applied from the variable voltage source 234 so as to control to acquire emission current to be targeted. The ammeter 238 can detect a value of the emission current.

The electron gun assembly 201 emits the electron beam 200. The entire first forming aperture plate 203 having a quadrilateral, for example, a rectangular hole, is illuminated, through the illumination lens 202, by the electron beam 200 emitted from the electron gun assembly 201. The electron beam 200 is formed so as to be quadrilateral, for example, rectangular. The forming lens 204 projects the electron beam 200 of a first aperture plate image that has passed through the first forming aperture plate 203, on the second forming aperture plate 206. The forming deflector 205 performs deflection control to a position of the first aperture plate image on the second forming aperture plate 206. Therefore, a shape and dimensions of the beam can be varied. As a result, the electron beam 200 is formed. The electron beam 200 of a second aperture plate image that has passed through the second forming aperture plate 206, is reduced through the reducing lens 216. Then, the electron beam 200 is focused through the objective lens 207 so as to be deflected by the main deflector 214 and the sub-deflector 212. As a result, a desired position on the target object 340 on the XY stage 105 that continuously moves is irradiated with the electron beam 200.

In a case where the electron beam 200 on the target object 340 satisfies beam irradiation time Δt during which a desired dose is incident on the target object 340, blanking is performed as follows: In order to prevent the target object 340 from being irradiated with the electron beam 200 more than necessary, for example, the electrostatic BLK deflector 218 deflects the electron beam 200 and also the BLK aperture plate 219 cuts off the electron beam 200. Accordingly, the electron beam 200 is prevented from reaching the surface of the target object 340. The pattern writing control circuit 240 controls a deflecting voltage of the BLK deflector 218. A vacuum pump (not illustrated) forms vacuums inside the electron optical column 102 and inside the pattern writing chamber 103. Thus, vacuum atmosphere in which pressure is lower than the atmospheric pressure, is provided.

Next, a mechanism for controlling current density J of the electron beam so as to be substantially constant during writing, and a method for controlling the current density J of the electron beam so as to be substantially constant during the writing, included in the electron beam lithography apparatus according to the present embodiment, will be described. First, while a desired pattern is written on the target object 340, the current density J is measured a plurality of times. A target value of the emission current Iₑ for correcting and converging a variation of the current density J into a desired constant value, is calculated each of the plurality of times. The target value is output to the electron gun assembly power source 230. The variable control is performed to the bias voltage in the electron gun assembly power source 230 during the writing so that the emission current Iₑ comes close to the target value. With this configuration, during the writing, the current density J can be maintained so as to be substantially constant.

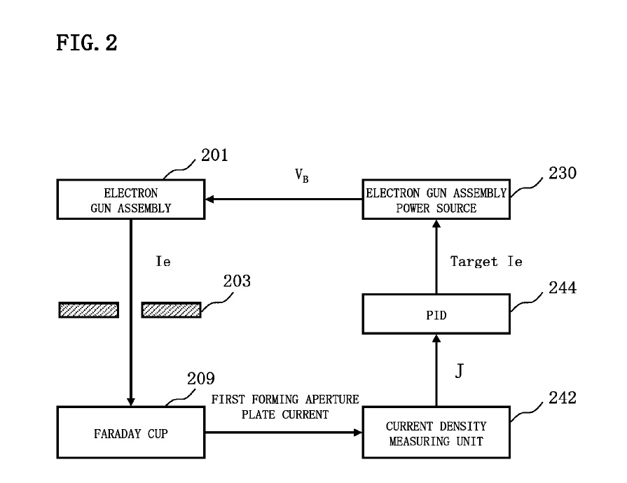

FIG. 2 is a conceptual diagram for describing a method for adjusting the current density of the electron beam according to the present embodiment. In FIG. 2, the electron gun assembly power source 230 performs feedback control to a value of the bias voltage V_{B} so that the emission current Iₑ, is set to the target value of the emission current. The electron gun assembly 201 emits the electron beam 200 of the emission current Iₑ. The Faraday cup 209 receives the entire beam that has passed through the first forming aperture plate 203 having a constant opening size. A first forming aperture plate current value acquired from current intensity received by the Faraday cup 209, is output to the current density measuring unit 242. Here, beam current of the entire beam that has passed through the first forming aperture plate 203 is defined as the first forming aperture plate current. In the current density measuring unit 242, the first forming aperture plate current value is divided by an opening area of the first forming aperture plate 203 so that the current density J is measured. The current density J is output to the PID controller 244. The PID controller 244 calculates the target value of the emission current Iₑ for converging the current density J in set current density J. The target value is output to the electron gun assembly power source 230. The electron gun assembly power source 230 performs feedback control to the bias voltage V_{B} so that the emission current Iₑ is set to the target value. The loop operation is performed a plurality of times during the writing on the target object 340.

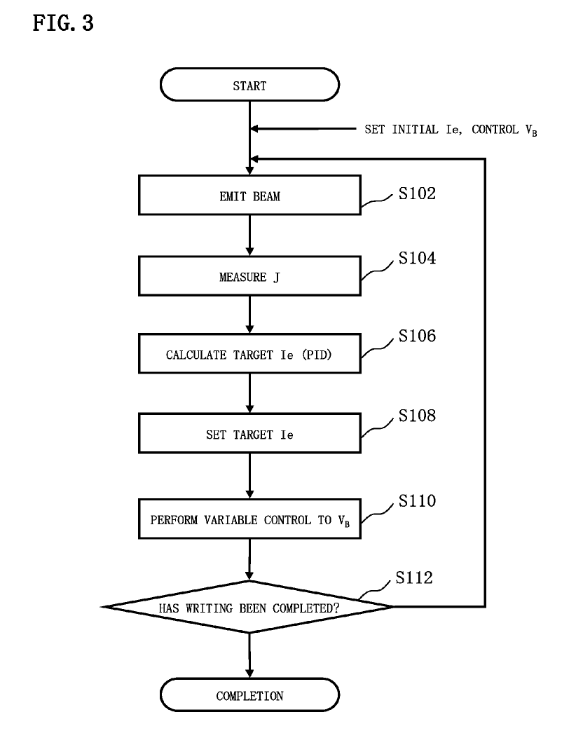

FIG. 3 is a flow chart of a series of main processes of the method for adjusting the current density of the electron beam according to the present embodiment. Firstly, an initial value of the emission current Iₑ is set in the second controller 232 of the electron gun assembly power source 230. The second controller 232 performs the variable control while performing the feedback control to the value of the bias voltage V_{B} so that the emission current Iₑ, comes close to the initial value to be the first target value of the emission current Iₑ. The writing of a predetermined pattern is started on the target object 340. During the writing, current density adjustment to be described below of the electron beam is performed a plurality of times during the writing. For example, the current density adjustment of the electron beam is performed every 10 to 30 minutes. The current density adjustment may be performed together in a beam position correction sequence periodically performed during the writing. As described above, there is no need for arranging additional time for the current density adjustment of the electron beam. Thus, degradation of throughput can be inhibited. The series of main processes of the method for adjusting the current density of the electron beam, will be described below.

At S (step) 102, as a beam irradiating process, the electron gun assembly 201 emits the electron beam 200 in which the emission current Iₑ is set to the target value. The electron gun assembly 201 is an example of irradiation sources.

At S104, as a current density measuring process, the current density measuring unit 242 measures the current density J of the electron beam 200 every time steps illustrated in FIG. 3 is repeated. That is, the current density J of the electron beam 200 is measured a plurality of times while the writing on the target object 340 is performed using the electron beam 200. As described above, in the method, the Faraday cup 209 receives the entire beam that has passed through the first forming aperture plate 203 having the constant opening size. More specifically, the electron beam 200 emitted from the electron gun assembly 201 is illuminated on the first forming aperture plate 203 through the illumination lens 202. In order to prevent an image of the first forming aperture plate 203 that has passed through the first forming aperture plate 203, from being shielded by the second forming aperture plate 206, the forming deflector 205 deflects the electron beam 200. The Faraday cup 209 measures beam current of the entire beam that has passed through the second forming aperture plate 206. Output of the Faraday cup 209 is transmitted to the current density measuring unit 242. In the current density measuring unit 242, the first forming aperture plate current value is divided by the opening area of the first forming aperture plate 203 so that the current density J is calculated. Measuring the first forming aperture plate current can prevent variations of the forming lens 204 and the forming deflector 205 (noises) from giving a harmful effect to current density calculating accuracy.

In the above example, the current density J is calculated from the entire beam that has been passed through the first forming aperture plate 203. The present disclosure is not limited to this. For example, the first forming aperture plate 203 and the second forming aperture plate 206 form a beam, for example, having an area of 1 square μm. Then, the Faraday cup 209 may measure the beam that has been formed. The current density J can be acquired by dividing a beam current value by the area that has been formed. As described above, determining the area to be formed in advance can measure the current density J.

At S106, as a target emission current calculating process, every time the current density J of the electron beam 200 is measured, the PID controller 244 calculates the target value of the emission current Iₑ that varies depending on the current density J of the electron beam 200 that has been measured, so that the current density J of the electron beam 200 becomes substantially constant. Every time the calculation is performed, the target value of the emission current Iₑ is output to the second controller 232. The PID controller 244 uses a PID method and calculates the target value of the emission current Iₑ so that the current density J converges in a constant value.

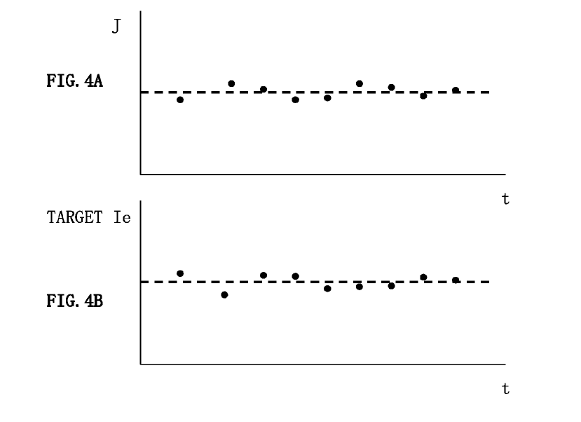

FIGS. 4A and 4B are graphical representations of examples of the current density J and the target value of the emission current Iₑ according to the present embodiment, respectively. FIG. 4A illustrates that the current density J converges as time passes. In order to achieve the convergence illustrated in FIG. 4A, the PID controller 244 uses the PID method so as to calculate the target value of the emission current Iₑ illustrated in FIG. 4B.

At S108, as a target emission current setting process, the second controller 232 inputs the target value of the emission current Iₑ so as to reset instead of a value that has been set.

At S110, as a bias voltage variable control process, the second controller 232 controls the electron gun assembly 201 based on the new target value of the emission current Iₑ.

At S112, as a determining process, it is determined whether the writing has been completed. In a case where the writing is still performed, the processing goes back to S102. As described above, for example, every 10 to 30 minutes, the series of processes from S102 to S112 is repeated. Accordingly, while the writing is performed on the target object 340 by using the electron beam 200, the current density J of the electron beam 200 is measured a plurality of times. Every time the measurement is performed, the target value of the emission current Iₑ is varied. When the writing is completed, the processing is completed. Otherwise, the above current density adjustment is preferably periodically performed for writing on a next target object 340 even when the writing is not performed. Accordingly, the current density J can be continuously kept substantially constant.

In the above example, a configuration in which the PID controller 244 calculates the target value of the emission current Iₑ so that the current density J of the electron beam 200 becomes substantially constant, has been given. The present disclosure is not limited to this. For example, a target value of the bias voltage V_{B} is preferably calculated so as to be output. In this case, there may be provided a configuration in which output of the variable voltage source 234 is varied so as to be equal to the target value of the bias voltage V_{B} input by the second controller 232.

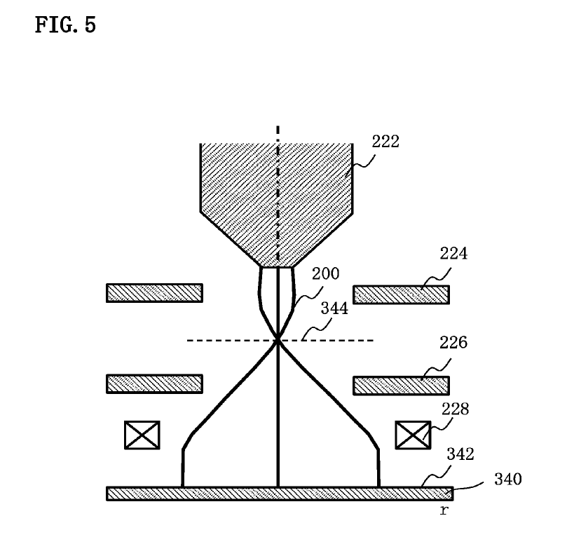

Next, a method for estimating a lifetime of the cathode in the electron beam lithography apparatus according to the present embodiment, will be described. FIG. 5 is a schematic view of the electron beam according to the present embodiment. The electron beam 200 emitted from the emitter 222 of the cathode 220 forms, on a crossover surface 344, a state called a crossover due to a lens field formed by the negative pole (cathode 220), the Wehnelt electrode 224, and the positive pole (anode 226). After that, the electron beam 200 spreads and is refracted through a collimator lens (illumination lens) 228 so as to be perpendicular to or substantially perpendicular to a target object surface 342. Then, the target object 340 is irradiated with the electron beam 200.

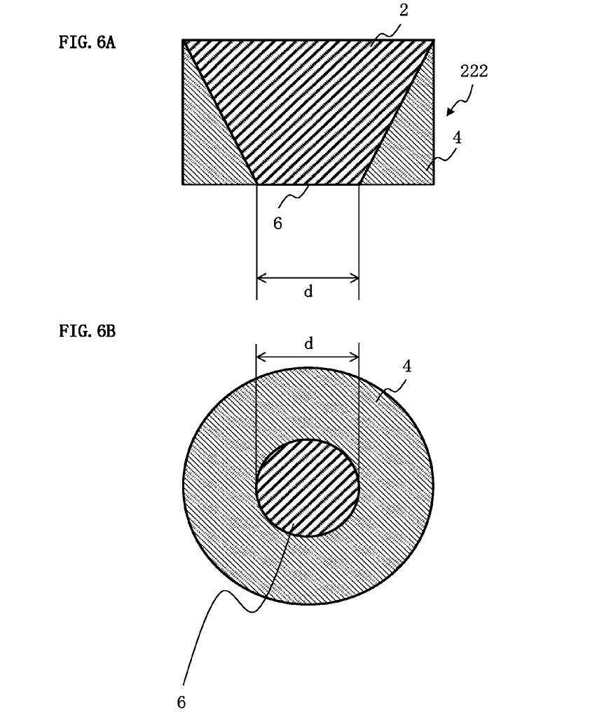

FIGS. 6A and 6B are schematic views of the emitter according to the present embodiment. The emitter 222 has lanthanum hexaboride 2 and carbon 4 disposed around the lanthanum hexaboride 2. The lanthanum hexaboride 2 has an emitter surface 6. The electron beam 200 described above is emitted from the emitter surface 6. A diameter d of the emitter surface 6 is referred to as an emitter diameter. For example, an emitter diameter acquired by observation of the emitter surface 6 using a microscope, such as an optical microscope, is referred to as an actual measured emitter diameter. Note that, in a case where a shape of the emitter surface 6 is elliptical, the shorter diameter and the longer diameter of the emitter surface 6 are measured. Then, an average between the shorter diameter and the longer diameter, is preferably calculated and acquired.

Note that, according to the embodiment of the present disclosure, materials can be used other than lanthanum hexaboride (LaB₆) as a material included in the emitter 222. The material included in the emitter 222 is required to have high electric conduction, mechanical strength and chemical stability at a high temperature. A material having a high melting point can achieve the mechanical strength and the chemical stability at the high temperature. Note that, more specifically, the high melting point is defined as a high melting point higher than an operating temperature of the electron beam lithography apparatus. Materials that satisfy the above properties and that have a low work function similar to that of lanthanum hexaboride (LaB₆), include metal hexaboride, such as cerium hexaboride (CeB₆), gadolinium hexaboride (GdB₆), and yttrium hexaboride (YB₆). For example, tungsten (W) can be also used as a material included in the emitter 222. Since tungsten (W) has a melting point higher than those of lanthanum hexaboride (LaB₆) and cerium hexaboride (CeB₆), for example, tungsten (W) can be used at, for example, a temperature of 2000 K.

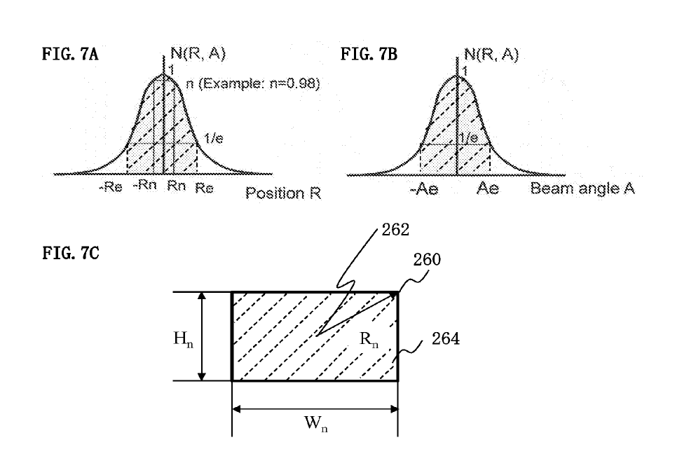

FIGS. 7A to 7C are schematic views of distributions of the electron beam 200 on the target object 340 according to the present embodiment. FIG. 7A is the schematic view of the distribution in a direction of a radius R of the electron beam 200. FIG. 7B is the schematic view of the distribution in a direction of an angle A of the electron beam 200. The angle is defined as a beam angle of the electron beam 200 with respect to an optical axis after the crossover described above. The distributions of the electron beam 200 illustrated in FIGS. 7A and 7B according to the present embodiment are Gaussian distributions. FIG. 7C is the schematic view of a shot 264 formed, by the electron beam 200, on the target object 340. A shape of the shot 264 illustrated in FIG. 7C includes a quadrilateral, such as a rectangle, having the long side (first side) with a length of Wₙ and the short side (second side) with a length of Hₙ. A position of an electron beam center 262 can be the center of gravity of the shot 264. For example, in a case where the shot 264 is rectangular, the position of an electron beam center 262 can be the center of the rectangle. An electron beam edge 260 is defined in advance as an edge of the shot 264 having the longest distance from the electron beam center 262. Note that, in a case where Wₙ=Hₙ is satisfied, the shape of the shot 264 is square.

As the cathode 220 is used, since a part of the material included in the cathode 220 evaporates, the diameter of the emitter surface 6 (refer to FIGS. 6A and 6B) decreases. Thus, uniformity of the beam degrades. Here, in a case where the uniformity of the beam is defined as n, if a distance between the electron beam center 262 and the electron beam edge 260 is defined as Rₙ, n can be calculated by the following expression (1) using current density J (Rₙ) of the electron beam edge 260 and current density J (0) of the electron beam center 262.

n=J(Rₙ)/J(0) (1)

The uniformity n of the beam is an example of a lifetime reference value of the cathode 220. If the uniformity n of the beam falls below a certain reference value, the cathode 220 is defined so as to be the end of lifetime thereof. For example, n is preferably in a range between 0.95 and 0.99. In the following descriptions, n is defined as 0.98.

In a case where the distribution of the electron beam 200 is a Gaussian distribution, and in a case where R is defined as a distance from the electron beam center 262 on the target object 340 and J₀ is defined as a constant, current density J(R) of the electron beam 200 can be expressed by the following expression.

J(R)=J₀exp(−R²/Rₑ²) (2)

Here, Rₑ is defined as a radius of the electron beam 200 with which the number of electrons per unit time becomes the number of electrons per unit time at the electron beam center 262 in the electron beam 200, multiplied by 1/e (e is defined as the base of a natural logarithm) on the target object 340 as illustrated in FIG. 7A. The uniformity n of the beam can be expressed by the following expression (3) with expression (1) and expression (2). As the cathode 220 is used, the diameter of the emitter surface 6 (refer to FIGS. 6A and 6B) decreases and Rₑ also decreases. Accordingly, n decreases by the following expression.

n=exp(−Rₙ²/Rₑ²) (3)

In a case where the shape of the shot 264 is rectangular illustrated in FIG. 7C, Rₙ is expressed by the following expression (4) with Wₙ and Hₙ.

Rₙ=1/2(Wₙ²+Hₙ²)^{0.5} (4)

Thus, Rₑ is expressed by the following expression (5) with expression (3) and expression (4).

$${R}_{e} = \frac{{( {W}_{n}^{2} + {H}_{n}^{2} )}^{0.5}}{2 {( - ln ( n ) )}^{0.5}} \qquad ( 5 )$$

Next, emittance of the cathode 220 will be described. The emittance of the cathode 220 is defined as an amount of a spread of the electron beam 200 emitted from the cathode 220. Here, a diameter of a guide of the spread of the electron beam 200 is expressed as 2Rₑ using the above Rₑ. Here, Aₑ is defined as an angle at which the number of electrons per unit time becomes the number of electrons per unit time at the electron beam center in the electron beam 200 (A=0)262 multiplied by 1/e (e is defined as the base of a natural logarithm) on the target object 340 as illustrated in FIG. 7B. In this case, a guide of the spread in an angle direction of the electron beam 200 is expressed as 2Aₑ by the sum of a spread in a positive angle direction and a spread in a negative angle direction. The emittance of the cathode 220 is defined as the product of 2Rₑ and 2Aₑ by the following expression.

Emittance=4RₑAₑ (6)

The emittance is expressed by the following expression (7) with expression (5) and expression (6).

$$Emittance = \frac{2 {{A}_{e} ( {W}_{n}^{2} + {H}_{n}^{2} )}^{0.5}}{{( - ln ( n ) )}^{0.5}} \qquad ( 7 )$$

In a case where the shape of the shot 264 is square, namely, Wₙ=Hₙ is satisfied, the emittance is expressed by the following expression (8).

$$Emittance = \frac{2.82 {W}_{n} {A}_{e}}{{( - ln ( n ) )}^{0.5}} \qquad ( 8 )$$

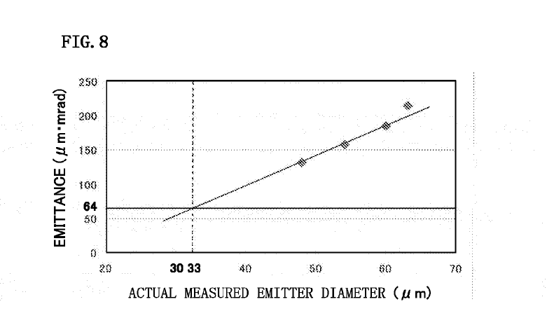

FIG. 8 is a graphical representation of the relationship between the emittance of the cathode 220 and the actual measured emitter diameter according to the present embodiment. Here, the emittance illustrated in FIG. 8 is an actual measured value. As illustrated in FIG. 8, an excellent correlation between the emittance and the actual measured emitter diameter, is observed. Therefore, an emitter lifetime diameter as the lifetime of the cathode 220 can be acquired from the uniformity n of the beam as the lifetime of the cathode 220. According to the present embodiment, the emittance is 64 μm mrad when n=0.98 is satisfied. Therefore, it is estimated that the emitter lifetime diameter is 33 μm. When once a change with time of the emitter diameter can be measured, the lifetime of the cathode 220 can be estimated. Note that, as the emittance, a value may be used based on a value acquired by each of expression (6), expression (7), and expression (8), such as a constant multiplication of each of expression (6), expression (7), and expression (8).

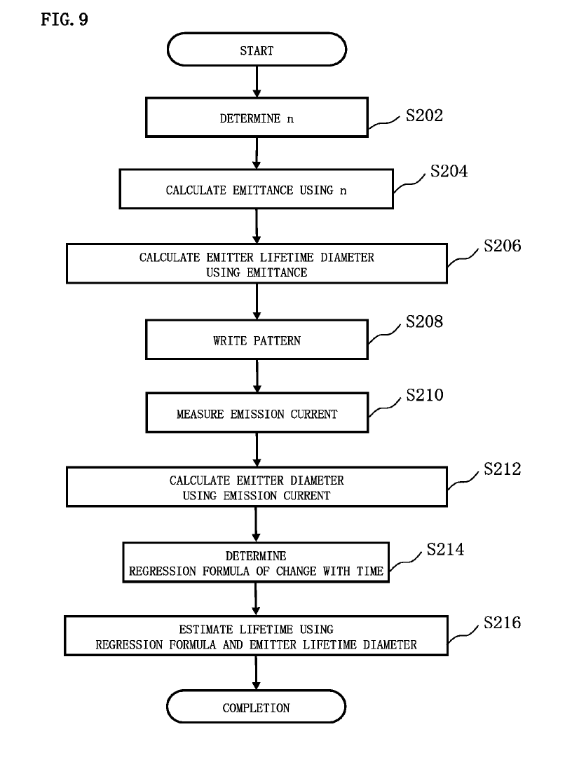

FIG. 9 is a flow chart of a series of main processes of the method for estimating the lifetime of the cathode in the electron beam lithography apparatus according to the present embodiment. The method for estimating the lifetime of the cathode in the electron beam lithography apparatus according to the present embodiment, performs the series of processes including a beam uniformity determining process (S202), an emittance calculating process (S204), an emitter lifetime diameter calculating process (S206), a writing process (S208), an emission current measuring process (S210), an emitter diameter calculating process (S212), a change-with-time regression formula determining process (S214), and a lifetime estimating process (S216).

First, the first controller 160 or an operator determines the uniformity n of the electron beam 200 at the beam uniformity determining process (S202). For example, a data storage unit 254 stores the uniformity n of the beam, the uniformity n having been determined.

Next, at the emittance calculating process (S204), the operator or the first controller 160 uses a first calculator 246 so as to calculate the emittance of the cathode by, for example, expression (6), expression (7), or expression (8), using n that has been determined at the beam uniformity determining process (S202). Here, for example, then that has been stored in the data storage unit 254, can be used as the uniformity n of the beam.

Next, at the emitter lifetime diameter calculating process (S206), the operator or the first controller 160 uses a second calculator 248 so as to calculate an emitter lifetime diameter of the cathode 220 by, for example, using the relationship illustrated in FIG. 8, with the emittance calculated at the emittance calculating process (S204).

Next, at the writing process (S208), the first controller 160 writes a pattern on the target object 340 using the electron beam 200 emitted from the cathode 220.

Next, at the emission current measuring process (S210), the operator or the first controller 160 uses the ammeter 238 so as to measure emission current Iₑ of the electron beam 200.

Next, at the emitter diameter calculating process (S212), the operator or the first controller 160 uses a third calculator 250 so as to calculate an emitter diameter d with the emission current Iₑ measured at the emission current measuring process (S210). In the electron beam lithography apparatus according to the present embodiment, current density J can be controlled to be constant. In this case, a relationship between the emission current Iₑ, the current density J, and the emitter diameter d, can be expressed by the following expression (9). Therefore, the emitter diameter d can be calculated.

$$J \times {π ( d \text{/} 2 )}^{2} = {I}_{e} \qquad ( 9 )$$

Next, at the change-with-time regression formula determining process (S214), the operator or the first controller 160 uses a processing unit 256 and, for example, plots a change with time of the emitter diameter d calculated at the emitter diameter calculating process (S212). Then, a regression formula of the change with time is determined.

Next, at the lifetime estimating process (S216), the operator or the first controller 160 uses a fourth calculator 252 so as to estimate the lifetime of the cathode 220 using the regression formula acquired at the change-with-time regression formula determining process (S214) and the emitter lifetime diameter calculated at the emitter lifetime diameter calculating process (S206).

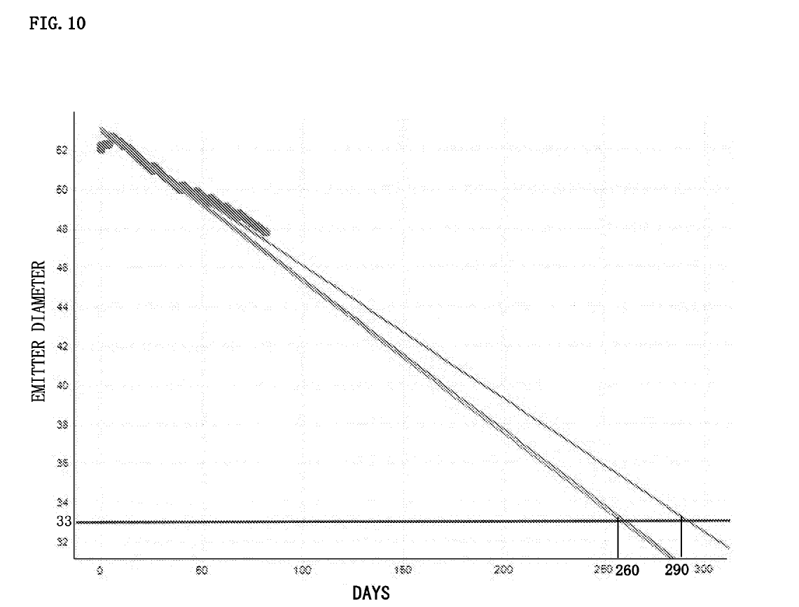

FIG. 10 is a graphical representation of the change with time of the emitter diameter d of the electron beam lithography apparatus according to the present embodiment. The graphical representation illustrated in FIG. 10 is acquired, for example, at the change-with-time regression formula determining process (S214). In FIG. 10, the regression formula of the change with time of the emitter diameter d is, for example, a linear expression, the regression formula being acquired at the change-with-time regression formula determining process (S214). In FIG. 10, the number of days during which the emitter diameter d becomes 33 μm, is estimated to be 260 days or 290 days in accordance with a range of days during which the emitter diameter has been measured. Note that the regression formula is not limited to a linear expression.

Upon operation of the electron beam lithography apparatus, estimating the lifetime of the cathode is preferable for maintenance of the electron beam lithography apparatus, including replacement of the cathode. The method for estimating the lifetime of the cathode in the electron beam lithography apparatus according to the present embodiment, can quantitatively estimate the lifetime of the cathode. In particular, as illustrated in FIG. 10, the change with time of the emitter diameter d is well expressed by the regression formula of a linear expression. Therefore, the lifetime can be simply estimated with high precision. As in FIG. 8, it is thought that an excellent linear relationship between the emittance and the emitter diameter d causes the above estimation to be possible.

The method for estimating the lifetime of the cathode in the electron beam lithography apparatus according to the present embodiment, can provides a method for estimating a lifetime of a cathode of an electron beam lithography apparatus, capable of performing quantitative estimation.

In the above descriptions, pieces of processing of functions of the first controller 160, the second controller 232, the current density measuring unit 242, the PID controller 244, the first calculator 246, the second calculator 248, the third calculator 250, the fourth calculator 252, and the processing unit 256, may be performed by software in a control calculator including a computer. Hardware of an electrical circuit may perform the pieces of processing of functions. A combination of the hardware of an electrical circuit and the software may perform the pieces of processing of functions. A combination of the hardware and firmware may be used. With a configuration of the software, a program is stored in a recording medium (not illustrated), such as a magnetic disk drive, a magnetic tape drive, a FD, or a read only memory (ROM). In that case, the control calculator may be coupled, via a bus, to a random access memory (RAM), the ROM, the magnetic disk (HD) drive, as an example of a data storage device (data storage unit), a keyboard (K/B), a mouse, as an example of an input unit, a monitor, a printer, as an example of an output unit, an external interface (I/F), a FD, a DVD, or a CD, as an example of an input-and-output unit.

According to the embodiment, parts, such as configurations, that are not directly necessary for describing the present disclosure, have been omitted. For example, a necessary configuration can be appropriately selected and used. With an element according to the present disclosure, a method for estimating a lifetime of a cathode in an electron beam lithography apparatus, appropriately changed and designed by a person skilled in the art, is included in the scope of the present disclosure. The scope of the present disclosure is defined by the scope of the claims and the scope of equivalents of the claims.

What is claimed is:

1. A method for estimating a lifetime of a cathode in an electron beam lithography apparatus, comprising:
calculating emittance of the cathode by using a lifetime reference value of the cathode;
calculating an emitter lifetime diameter of the cathode by using the emittance;
writing a pattern on a target object by using an electron beam emitted from the cathode;
measuring emission current of the electron beam;
calculating an emitter diameter by using the emission current;
determining a regression formula of a change with time of the emitter diameter; and
estimating the lifetime of the cathode by using the regression formula and the emitter lifetime diameter.

2. The method according to claim 1,
wherein a following expression (9) is used so as to calculate the emitter diameter d:
$$J \times {π ( d \text{/} 2 )}^{2} = {I}_{e} \qquad ( 9 )$$
where J represents current density of the electron beam, and Iₑ represents the emission current.

3. The method according to claim 1,
wherein a following expression (1) is used so as to calculate the lifetime reference value n:
n=J(Rₙ)/J(0) (1)
where Rₙ represents a distance between an electron beam center and an electron beam edge of a shot formed on the target object by the electron beam, J(Rₙ) represents current density at the electron beam edge, and J(0) represents current density at the electron beam center.

4. The method according to claim 3,
wherein a following expression (6) is used so as to calculate the emittance:
Emittance=4RₑAₑ (6)
where Aₑ represents an angle at which the number of electrons per unit time of the electron beam becomes the number of electrons per unit time at the electron beam center of the electron beam, multiplied by 1/e, and
Rₑ represents a radius of the electron beam at which the number of electrons per unit time of the electron beam on the target object becomes the number of electrons per unit time at the electron beam center of the electron beam, multiplied by 1/e.

5. The method according to claim 4,
wherein the following expression (7) is used so as to calculate the emittance:
$$Emittance = \frac{2 {{A}_{e} ( {W}_{n}^{2} + {H}_{n}^{2} )}^{0.5}}{{( - ln ( n ) )}^{0.5}} \qquad ( 7 )$$
where, in a case where a shape of the shot is rectangular, Wₙ represents length of a first side of the rectangle, and Hₙ represents length of a second side of the rectangle.

6. The method according to claim 4,
wherein the following expression (8) is used so as to calculate the emittance:
$$Emittance = \frac{2.82 {W}_{n} {A}_{e}}{{( - ln ( n ) )}^{0.5}} \qquad ( 8 )$$
where, in a case where a shape of the shot is square, Wₙ represents length of a side of the square.

7. The method according to claim 4,
wherein, in a case where a distribution of the electron beam is a Gaussian distribution, current density of the electron beam is expressed by the following expression (2):
J(R)=J₀exp(−R²/Rₑ²) (2)
where R represents a distance from an electron beam center on the target object.
